(19) United States
(12) Patent Application Publication
(10) Pub. No.: US 2026/0082640 A1
(43) Pub. Date: Mar. 19, 2026

(54) SEMICONDUCTOR DEVICE

(71) Applicant: Kioxia Corporation, Tokyo (JP)

(72) Inventor: Masato SHINI, Mie Mie (JP)

(21) Appl. No.: 19/070,421

(22) Filed: Mar. 4, 2025

(30) Foreign Application Priority Data
Sep. 18, 2024 (JP) 2024-161446

(51) Int. Cl. H10D 62/10; H10D 64/27; H10D 64/68; H10D 84/01; H10D 84/85

(52) U.S. Cl. CPC H10D 62/102; H10D 64/27; H10D 64/691; H10D 84/0188; H10D 84/85

(57) ABSTRACT

A semiconductor device includes a semiconductor substrate including a first surface and a second surface that is opposite to the first surface, the first surface including first and second channel surfaces, an element isolation portion in the semiconductor substrate and by which the first and second channel surfaces are insulated from each other, a first transistor including a first gate insulation film on the first channel surface and a first gate electrode on the first gate insulation film, a second transistor including a second gate insulation film on the second channel surface and a second gate electrode on the second gate insulation film, and a third electrode on the element isolation portion. A bottom portion of the third electrode is embedded in the element isolation portion to be closer to the second surface of the substrate than the first and second channel surfaces.

### CROSS-REFERENCE TO RELATED APPLICATION(S)

This application is based upon and claims the benefit of priority from Japanese Patent Application No. 2024-161446, filed Sep. 18, 2024, the entire contents of which are incorporated herein by reference.

### FIELD

Embodiments described herein relate generally to a semiconductor device.

### BACKGROUND

A known semiconductor device includes a semiconductor substrate and a plurality of transistors provided on the semiconductor substrate. In this type of semiconductor device, the interval between the transistors has become smaller due to higher integration of circuits. The transistors on the semiconductor substrate are individually insulated and isolated by an element isolation portion embedded in a surface layer of the semiconductor substrate.

### BRIEF DESCRIPTION OF THE DRAWINGS

FIG. 1 is a plan view illustrating a configuration of a semiconductor device according to a first embodiment.

FIG. 2 is a partial cross-sectional view along the A1-A2 line in FIG. 1.

FIG. 3 is a cross-sectional view illustrating a method for manufacturing the semiconductor device according to the first embodiment.

FIG. 4 is a cross-sectional view illustrating the method for manufacturing the semiconductor device according to the first embodiment.

FIG. 5 is a cross-sectional view illustrating the method for manufacturing the semiconductor device according to the first embodiment.

FIG. 6 is a cross-sectional view illustrating the method for manufacturing the semiconductor device according to the first embodiment.

FIG. 7 is a cross-sectional view illustrating the method for manufacturing the semiconductor device according to the first embodiment.

FIG. 8 is a cross-sectional view illustrating the method for manufacturing the semiconductor device according to the first embodiment.

FIG. 9 is a cross-sectional view illustrating the method for manufacturing the semiconductor device according to the first embodiment.

FIG. 10 is a cross-sectional view illustrating the method for manufacturing the semiconductor device according to the first embodiment.

FIG. 11 is a cross-sectional view illustrating the method for manufacturing the semiconductor device according to the first embodiment.

FIG. 12 is a cross-sectional view illustrating the method for manufacturing the semiconductor device according to the first embodiment.

FIG. 13 is a cross-sectional view illustrating a semiconductor device of a comparative example.

### DETAILED DESCRIPTION

Embodiments provide a semiconductor device capable of reducing the width of an element isolation portion that insulates and isolates transistors disposed separately from each other at a semiconductor substrate and contributing to the high integration of the transistors.

In general, according to one embodiment, A semiconductor device comprises: a semiconductor substrate including a first surface and a second surface that is opposite to the first surface, the first surface including first and second channel surfaces; an element isolation portion in the semiconductor substrate and by which the first and second channel surfaces are insulated from each other; a first transistor including a first gate insulation film on the first channel surface and a first gate electrode on the first gate insulation film; a second transistor including a second gate insulation film on the second channel surface and a second gate electrode on the second gate insulation film; and a third electrode on the element isolation portion. A bottom portion of the third electrode is embedded in the element isolation portion to be closer to the second surface of the substrate than the first and second channel surfaces.

Embodiments will be described below with reference to the accompanying drawings. In the following description, configurations having the same or similar functions are denoted by the same reference signs. The duplicate descriptions of these configurations may be omitted. “Parallel”, “orthogonal” or “the same” may include “substantially parallel”, “substantially orthogonal”, or “substantially the same”. “Connection” is not limited to a mechanical connection, but may include an electrical connection. That is, “connection” is not limited to a case in which elements are directly connected to each other, but may also include a case in which elements are connected with each other with another element interposed therebetween. “Facing” means that two members overlap when viewed in a certain direction, and may also include a case in which another member is present between the two members.

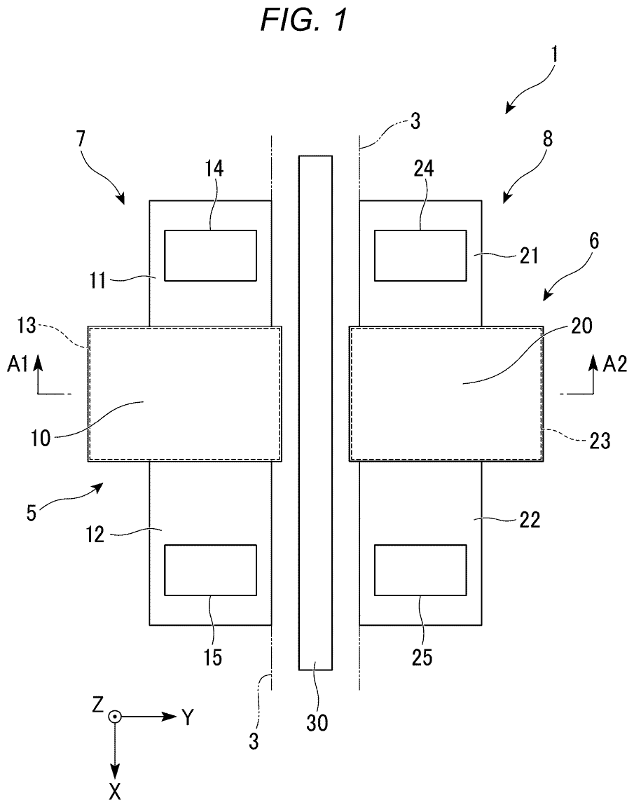

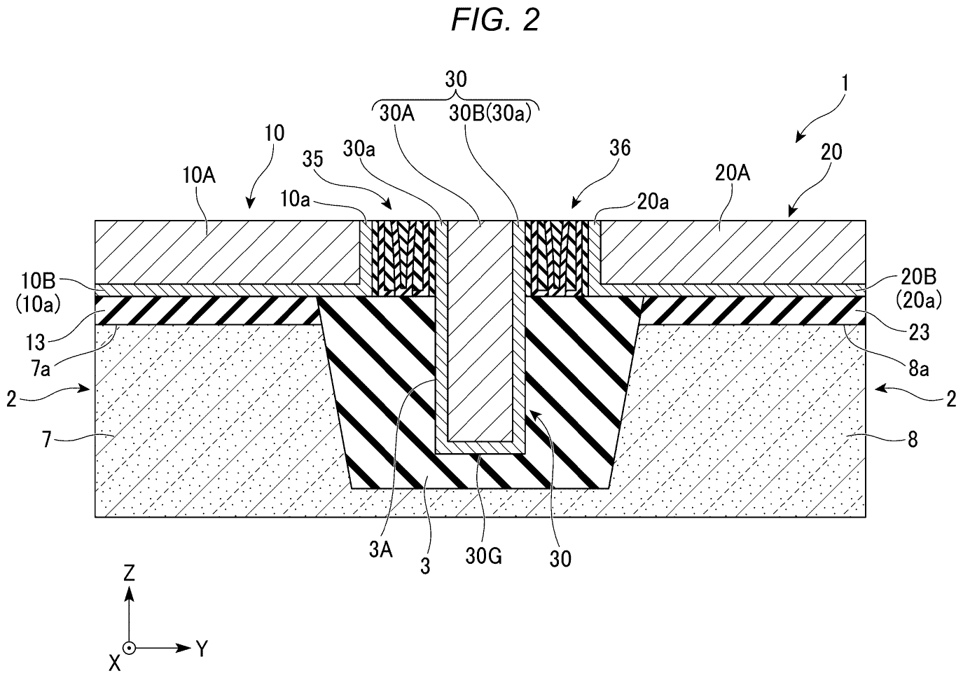

First, an X direction, a Y direction, and a Z direction are defined. The X direction and the Y direction are directions along the surface of a semiconductor substrate 2 to be described below (see FIG. 1 and FIG. 2). The X direction is a direction from a first source region 11 toward a first drain region 12 in a first transistor 5 to be described below (see FIG. 1), and a direction from a second source region 21 toward a second drain region 22 in a second transistor 6 to be described below (see FIG. 1). The Y direction is a direction intersecting (e.g., orthogonal to) the X direction. The Z direction is a direction intersecting (e.g., orthogonal to) the X direction and the Y direction. The Z direction is a thickness direction of the semiconductor substrate 2 (see FIG. 2). In the following description, a side on which gate electrodes 10 and 20 are located with respect to the semiconductor substrate 2 may be referred to as “upper” and the opposite side thereof may be referred to as “lower”. However, these expressions are for convenience only, and do not define the upper and lower sides along the direction of gravity.

### First Embodiment

### Configuration Example of Semiconductor Device

FIG. 1 is a plan view illustrating a configuration of a semiconductor device 1 according to a first embodiment. The semiconductor device 1 of the present embodiment is provided as a part of a circuit board of a semiconductor storage device such as a NAND flash memory. The semiconductor device 1 includes, for example, a semiconductor substrate 2, a plurality of transistors, and a plurality of wiring. The plurality of transistors are provided on the semiconductor substrate 2.

### Configurations of Semiconductor Substrate, Element Isolation Portion, and Transistors

Next, the configurations of the semiconductor substrate 2 and a first transistor 5 and a second transistor 6 will be described in detail.

FIG. 1 is a schematic plan view illustrating an arrangement example of the first transistor 5 and the second transistor 6 which are formed at a semiconductor substrate surface.

The semiconductor substrate 2 is, for example, a silicon substrate containing monocrystalline silicon. As illustrated in FIG. 2, one or more element isolation insulation regions 3 (hereinafter referred to as “element isolation portions 3”), which are formed of an insulator such as silicon oxide, are embedded in a surface layer portion of the semiconductor substrate 2. For example, in a plan view of the semiconductor substrate 2, the element isolation portion 3 has a predetermined width and surrounds the circumference of the first transistor 5 and the circumference of the second transistor 6. The first transistor 5 and the second transistor 6 are separated from each other in a surface direction of the semiconductor substrate 2.

The element isolation portion 3 is provided at a position between the first transistor 5 and the second transistor 6 along the X direction in FIG. 1. For the element isolation portion 3 provided between the first transistor 5 and the second transistor 6, only the position of the element isolation portion 3 is schematically illustrated in FIG. 1. It should be noted that, in order to insulate and isolate the region in which the first transistor 5 is formed from surrounding regions, the element isolation portion 3 surrounds the circumference of the first transistor 5 in a plan view, but only a part of the element isolation portion 3 is illustrated in FIG. 1. In addition, in order to insulate and isolate the region in which the second transistor 6 is formed from surrounding regions, the element isolation portion 3 surrounds the circumference of the second transistor 6 in a plan view, but only a part of the element isolation portion 3 is illustrated in FIG. 1.

In FIG. 2 illustrating a partial cross-sectional view along the A1-A2 line indicated in FIG. 1, the element isolation portion 3 is embedded in the semiconductor substrate 2, for example, so as to have a predetermined width and reach a predetermined depth from the front surface side of the semiconductor substrate 2. In the form illustrated in FIG. 2, the element isolation portion 3 is formed to have an inverted trapezoid cross-section.

The first transistor 5 and the second transistor 6 are respectively provided on both sides in the Y direction of the element isolation portion 3 extending in a strip shape in the X direction illustrated in FIG. 1. As can be seen from FIG. 1 and FIG. 2, the first transistor 5 and the second transistor 6 are respectively provided on both sides of the element isolation portion 3 in the width direction. Therefore, for convenience, the semiconductor substrate 2 in the region in which the first transistor 5 is formed is referred to as a first substrate portion 7, and the semiconductor substrate 2 in the region in which the second transistor 6 is formed is referred to as a second substrate portion 8, and will be described below.

The partial cross-section illustrated in FIG. 2 illustrates only a surface layer region close to the front surface of the semiconductor substrate 2, in which only regions close to the element isolation portion 3 on both sides of the element isolation portion 3 in the Y direction are illustrated, and only a region close to the element isolation portion 3 on the upper side (i.e., the Z direction side) of the element isolation portion 3 is illustrated. Accordingly, in FIG. 2, the illustration of regions below (i.e., on the −Z direction side of) the bottom portion of the element isolation portion 3 is omitted, and only a part of the first transistor 5 adjacent to the element isolation portion 3 is illustrated, and only a part of the second transistor 6 adjacent to the element isolation portion 3 is illustrated.

The first substrate portion 7 is a base portion for providing the first transistor 5, and the second substrate portion 8 is a base portion for providing the second transistor 6. The first substrate portion 7 and the second substrate portion 8 each include, in at least a part of the regions in which the transistors are provided, a source region and a drain region, which will be described below, and a well region having a different polarity (i.e., different conductive type) from the source region and the drain region.

### 2.2 Transistors

Each of the first transistor 5 and the second transistor 6 is a field-effect transistor, for example a metal-oxide semiconductor field-effect transistor (MOSFET).

In a circuit board of a semiconductor storage device such as a NAND flash memory, a high-voltage transistor for outputting a relatively high voltage (e.g., 20 V or higher) and a low-voltage transistor for outputting a relatively low voltage (e.g., 10 V or lower) are provided. As an example, the first transistor 5 and the second transistor 6 are both high-voltage transistors capable of outputting about 30 V.

### First Transistor

The first transistor 5 includes, for example, a first gate electrode 10, a first source region 11, a first drain region 12, and a first gate insulation film 13. Hereinafter, the first source region 11 is also referred to as a “first diffusion layer region”, and the first drain region 12 is also referred to as a “second diffusion layer region”. Additionally, the first drain region 12 may also be referred to as the “first diffusion layer region” and the first source region 11 may also be referred to as the “second diffusion layer region”. The first transistor 5 preferably includes a high dielectric constant film (e.g., an insulation film) such as a hafnium oxide film called High-k between the first gate electrode 10 and the first gate insulation film 13. The high dielectric constant film is a film having a dielectric constant higher than SiO2 constituting the semiconductor substrate 2.

The first source region 11 and the first drain region 12 are diffusion layer regions formed by ion implantation at positions separated from each other in the X direction on the surface of the first substrate portion 7. A first channel region is formed between the first source region 11 and the first drain region 12 in the surface layer portion of the first substrate portion 7. The first gate insulation film 13 covers a part of the first channel region, a part of the first source region 11, and a part of the first drain region 12. The first gate electrode 10 covers the upper surface of the first gate insulation film 13. The first gate electrode 10 is provided on the opposite side of the first substrate portion 7 of the semiconductor substrate 2 with respect to the first gate insulation film 13.

In FIG. 1, the channel region provided below the first gate insulation film 13 is hidden by the first gate electrode 10 and is not illustrated. As described above, in the surface layer portion of the first substrate portion 7 below the first gate insulation film 13, a region sandwiched between the first source region 11 and the first drain region 12 is the first channel region. In FIG. 2, only the peripheral regions of the element isolation portion 3 are illustrated, and thus only a part of the first gate insulation film 13 provided at the first transistor 5 is illustrated. The surface layer region of the first substrate portion 7 located below the first gate insulation film 13 is the first channel region, and the surface of the first channel region on the side of the first gate insulation film 13 is a first channel surface. The channel surface of the first transistor 5 is a surface denoted by the reference sign 7a in FIG. 2.

For example, the first gate insulation film 13 is made of a silicon oxide film obtained by oxidizing the upper surface layer of the first substrate portion 7. Thus, the first gate insulation film 13 is formed to have a predetermined depth from the upper surface position of the first substrate portion 7. The element isolation portion 3 is formed such that a groove is formed in the front surface of the semiconductor substrate 2 and the groove is filled with an insulator.

For example, the first gate electrode 10 includes a main body electrode portion 10A made of a metal such as tungsten or aluminum, and a stacked film 10B covering the circumference surface and side surfaces of the main body electrode portion 10A.

For example, the stacked film 10B is made of a stacked film in which the required number of insulation films and metal films are stacked in the order from a side closer to the gate insulation film 13. In the stacked film 10B, a film in contact with the gate insulation film 13 is preferably made of a high dielectric constant film such as a hafnium oxide film called High-k. In FIG. 2, the stacked film 10B in which a plurality of films is stacked is simply illustrated as a single film, but since the film closest to the gate insulation film 13 may include a high dielectric constant film 10a, the reference sign 10a indicating the presence of the high dielectric constant film is also indicated. The stacked film 10B can be described as a film containing a high dielectric constant material.

For example, the stacked film 10B can be manufactured by diverting a part of a plurality of films used when a CMOS type metal gate transistor is manufactured by forming a P-type region and an N-type region in one P-type semiconductor substrate 2.

A region 14 illustrated in FIG. 1 indicates a region in which a contact electrode connected to the upper surface of the first source region 11 is provided, and a region 15 indicates a region in which a contact electrode connected to the upper surface of the first drain region 12 is provided. The regions 14 and 15 are illustrated as having a rectangular shape in FIG. 1, but may have other shapes, such as a circular shape.

FIG. 2 illustrates a state in which after the stacked film 10B and the main body electrode portion 10A are formed, the upper surface side is polished by chemical-mechanical polishing (CMP) to make the upper surface flush. After polishing by CMP, an insulation layer having a predetermined thickness is formed on the polished surface, and a hole communicating with the first source region 11 is made in the insulation layer, a hole communicating with the first drain region 12 is made in the insulation layer, and the portions in which the holes are made are filled with a metal serving as the contact electrodes, with forming silicide layers as necessary. As a result, the contact electrode is connected to the first source region 11 and the contact electrode is connected to the first drain region 12. In addition, by forming a contact electrode connected to the gate electrode 10 at the insulation layer, the gate electrode 10 can be energized and the first transistor 5 becomes operable.

### Second Transistor

The second transistor 6 includes, for example, a second gate electrode 20, a second source region 21, a second drain region 22, and a second gate insulation film 23. The second source region 21 is also referred to as a “third diffusion layer region”, and the second drain region 22 is also referred to as a “fourth diffusion layer region”. Additionally, the second drain region 22 may also be referred to as the “third diffusion layer region”, and the second source region 21 may also be referred to as the “fourth diffusion layer region”. The second transistor 6 preferably includes a high dielectric constant film (e.g., an insulation film) such as a hafnium oxide film called High-k between the second gate electrode 20 and the second gate insulation film 23.

The second source region 21 and the second drain region 22 are diffusion layer regions formed by ion implantation at positions separated from each other in the X direction on the surface of the second substrate portion 8. A second channel region is formed between the second source region 21 and the second drain region 22 in the surface layer portion of the second substrate portion 8. The second gate insulation film 23 covers a part of the second channel region, a part of the second source region 21, and a part of the second drain region 22. The second gate electrode 20 covers the upper surface of the second gate insulation film 23. The second gate electrode 20 is provided on the opposite side of the second substrate portion 8 of the semiconductor substrate 2 with respect to the second gate insulation film 23.

In FIG. 1, the second channel region provided below the second gate insulation film 23 is hidden by the second gate electrode 20 and is not illustrated. As described above, in the surface layer portion of the second substrate portion 8 below the second gate insulation film 23, a region sandwiched between the second source region 21 and the second drain region 22 is the second channel region. In FIG. 2, only the peripheral regions of the element isolation portion 3 are illustrated, and thus only a part of the second gate insulation film 23 provided at the second transistor 6 is illustrated. The surface layer region of the second substrate portion 8 located below the second gate insulation film 23 is the second channel region, and the surface of the second channel region on the side of the second gate insulation film 23 is a second channel surface. The channel surface of the second transistor 6 is a surface denoted by the reference sign 8a in FIG. 2.

For example, the second gate insulation film 23 is made of a silicon oxide film obtained by oxidizing a part of the upper surface of the second substrate portion 8. Thus, the second gate insulation film 23 is formed to have a predetermined depth from the upper surface position of the second substrate portion 8. The element isolation portion 3 is formed such that a groove is formed in the front surface of the semiconductor substrate 2 and the groove is filled with an insulator.

For example, the second gate electrode 20 includes a main body electrode portion 20A made of a metal such as tungsten or aluminum, and a stacked film 20B covering the circumference surface and side surfaces of the main body electrode portion 20A.

For example, the stacked film 20B is made of a stacked film in which the required number of insulation films and metal films are stacked in the order from a side closer to the gate insulation film 23. In the stacked film 20B, a film in contact with the gate insulation film 23 is preferably made of a high dielectric constant film such as a hafnium oxide film called High-k. In FIG. 2, the stacked film 20B in which a plurality of films is stacked is simply illustrated as a single film, but since the film closest to the gate insulation film 23 may include the high dielectric constant film 20a, the reference sign 20a indicating the presence of the high dielectric constant film is also indicated. The stacked film 20B can be described as a film containing a high dielectric constant material.

For example, the stacked film 20B can be manufactured by diverting a part of a plurality of films used when a CMOS type metal gate transistor is manufactured by forming a P-type region and an N-type region in one P-type semiconductor substrate 2.

A region 24 illustrated in FIG. 1 indicates a region in which a contact electrode connected to the upper surface of the second source region 21 is provided, and a region 25 indicates a region in which a contact electrode connected to the upper surface of the second drain region 22 is provided. The regions 24 and 25 are illustrated as having a rectangular shape in FIG. 1, but may have other shapes, such as a circular shape.

FIG. 2 illustrates a structure in which after the stacked film 20B and the main body electrode portion 20A are formed, the upper surface side is polished by chemical-mechanical polishing (CMP) to make the upper surface flush. After polishing by CMP, an insulation layer having a predetermined thickness is formed on the polished surface, and a hole communicating with the second source region 21 is made in the insulation layer, a hole communicating with the second drain region 22 is made in the insulation layer, and the portions in which the holes are made are formed with a metal layer serving as the contact electrodes, with forming silicide layers as necessary. As a result, the contact electrode is connected to the second source region 21 and the contact electrode is connected to the second drain region 22. In addition, by forming a contact electrode connected to the second gate electrode 20 at the insulation layer, the second gate electrode 20 can be energized and the second transistor 6 becomes operable.

### Third Electrode

In the present embodiment, a third electrode 30 serving as a shield gate electrode, is provided to the element isolation portion 3 extending between the first transistor 5 and the second transistor 6.

The third electrode 30 is formed along a concave groove 3A formed along the length direction (i.e., the X direction) of the element isolation portion 3 at the center of the upper surface of the element isolation portion 3. The depth of the concave groove 3A is deeper than the channel surface 7a of the first transistor 5 and the channel surface 8a of the second transistor 6, and is a depth that does not penetrate the element isolation portion 3 in a depth direction.

The channel region of the first transistor 5 refers to a region in which electrons move in the surface layer portion of the first substrate portion 7 between the first source region 11 and the first drain region 12. The channel region of the second transistor 6 refers to a region in which electrons move in the surface layer portion of the second substrate portion 8 between the second source region 21 and the second drain region 22.

For example, the width in the Y direction of the concave groove 3A is preferably a fraction of the width in the Y direction of the element isolation portion 3.

In the concave groove 3A of the element isolation portion 3, the third electrode 30 having a partition wall shape extends from the bottom portion of the concave groove 3A, through the upper portion of the concave groove 3A, to between the first gate electrode 10 of the first transistor 5 and the second gate electrode 20 of the second transistor 6.

The third electrode 30 includes an electrode main body portion 30A formed in the middle in the width direction of the third electrode 30, and a stacked film 30B covering the circumferential surface and bottom surface of the electrode main body portion 30A. For example, the electrode main body portion 30A is made of a metal such as tungsten or aluminum.

For example, the stacked film 30B can be manufactured by diverting a part of a plurality of films used when a CMOS type metal gate transistor is manufactured by forming a P-type region and an N-type region in one P-type semiconductor substrate 2.

For example, the stacked film 30B is made of a stacked film in which the required number of insulation films and metal films are stacked in the order from a side closer to the concave groove 3A. In the stacked film 30B, a film in contact with an inner surface of the concave groove 3A is preferably made of a high dielectric constant film such as a hafnium oxide film called High-k. In FIG. 2, the stacked film 30B in which a plurality of films is stacked is simply illustrated as a single film, but since the film closest to the inner surface of the concave groove 3A may include a high dielectric constant film 30a, the reference sign 30a indicating the presence of the high dielectric constant film is also indicated. The stacked film 30B can be described as a film containing a high dielectric constant material.

As described above, the stacked film 30B has the same film type and structure as the stacked film 10B formed around the first gate electrode 10 and the stacked film 20B formed around the second gate electrode 20.

As illustrated in FIG. 2, a first insulation portion 35 is formed between the side surface of the first gate electrode 10 at the +Y direction end and the side surface of the third electrode 30, which is adjacent to the first gate electrode 10, at the −Y direction end. Specifically, the first insulation portion 35 is formed between the side surface of a first layer 10a located at the +Y direction end of the stacked film 10B and the side surface of a first layer 30a located at the −Y direction end of the stacked film 30B. The first insulation portion 35 insulates and isolates the first gate electrode 10 and the third electrode 30 from each other.

As illustrated in FIG. 2, a second insulation portion 36 is formed between the side surface of the second gate electrode 20 at the −Y direction end and the side surface of the third electrode 30, which is adjacent to the second gate electrode 20, at the +Y direction end. Specifically, the second insulation portion 36 is formed between the side surface of a first layer 20a located at the −Y direction end of the stacked film 20B and the side surface of the first layer 30a located at the +Y direction end of the stacked film 30B. The second insulation portion 36 insulates and isolates the second gate electrode 20 and the third electrode 30 from each other.

The bottom portion of the concave groove 3A in which the third electrode 30 is provided is located at a position deeper than the channel surfaces 7a and 8a in the thickness direction (i.e., the Z direction) of the semiconductor substrate 2. Thus, a bottom portion 30G of the third electrode 30 is located at a position deeper in the −Z direction than the channel surface 7a of the first transistor 5 and deeper than the channel surface 8a of the second transistor 6 in the thickness direction of the semiconductor substrate 2. However, preferably, the third electrode 30 does not penetrate the element isolation portion 3 in the thickness direction (i.e., the Z direction) of the semiconductor substrate 2.

The first insulation portion 35 can be manufactured by diverting a protective film, an insulation film, an insulation layer, or the like used when the first transistor 5 and second transistor 6 of a CMOS type are manufactured. FIG. 1 illustrates only the first source region 11, the first drain region 12, the gate insulation film 13, and the first gate electrode 10 as the main elements of the first transistor 5. On the other hand, as an example of the CMOS-type first transistor 5, a structure in which a cap insulation film is disposed on the gate electrode 10, both sides thereof are covered with insulation sidewalls, and a plurality of liner insulation films is stacked on these elements.

These insulation films and insulation sidewalls are made of insulation films such as silicon oxide or silicon nitride. The plurality of insulation films used here forms the first insulation portion 35 and the second insulation portion 36.

The third electrode 30 extends between the first gate electrode 10 and the second gate electrode 20 with the first insulation portion 35 and the second insulation portion 36 interposed therebetween. Thus, the third electrode 30 separates the first gate electrode 10 and the second gate electrode 20 from each other. The bottom portion 30G of the third electrode 30 may be formed at a position deeper in the −Z direction in the semiconductor substrate 2 than the channel region of the first transistor 5 and the channel region of the second transistor 6.

In the present embodiment, a voltage of about 30 V may be applied to the first gate electrode 10 and the second gate electrode 20, and the potential of the third electrode 30 provided at the element isolation portion 3 can be set to 0 V. By providing the third electrode 30 with a potential of 0 V, the electric field effect of cut-off becomes strong, and a shielding effect is obtained. As a result, it is possible to prevent an inter-element leak current from leaking from the source/drain region of the first transistor 5 to the side of the second transistor 6 through the bottom portion side of the element isolation portion 3. On the contrary, it is possible to prevent an inter-element leak current from leaking from the source/drain region of the second transistor 6 to the side of the first transistor 5 through the bottom portion side of the element isolation portion 3.

In addition, since the inter-element leak current can be prevented by providing the third electrode 30, the element isolation breakdown voltages of the first transistor 5 and the second transistor 6 can be improved as compared to a structure in the related art in which the third electrode 30 is not provided in the concave groove. In addition, since the element isolation breakdown voltages are improved, the element isolation portion 3 can be set to have a narrower width than the structure in the related art, and the interval between the first transistor 5 and the second transistor 6 can be reduced. Accordingly, the high integration of the transistors installed can be achieved.

### Structure Example of Transistor

Currently, in a highly-integrated semiconductor storage device, the depth of the element isolation portion 3 is about 350 nm, and the width in the Y direction of the first source region 11 and the first drain region 12 illustrated in FIG. 1 is about 1800 nm. The width in the X-direction of the first gate electrode 10 illustrated in FIG. 1 is about 1800 nm, the interval in the X direction between the first gate electrode 10 and the region 14 is about 600 nm, and the interval in the X direction between the first gate electrode 10 and the region 15 is about 690 nm.

With these dimensions, the width in the Y direction of the third electrode 30 can be set to about 150 nm, the interval in the Y direction between the third electrode 30 and the first gate electrode 10 can be set to about 125 nm, and the interval in the Y direction between the third electrode 30 and the second gate electrode 20 can be set to about 125 nm. The distance of protrusion of the end of the first gate electrode 10 in the +Y direction from the ends of the first source region 11 and the first drain region 12 in the +Y direction to the third electrode 30 side can be set to about 100 nm. The distance of protrusion of the end of the second gate electrode 20 in the −Y direction from the ends of the second source region 21 and the second drain region 22 in the −Y direction to the third electrode 30 side can be set to about 100 nm.

In the above case, when a concave groove having a depth of 320 nm is formed in the element isolation portion 3 and the height of the first insulation portion 35 and the second insulation portion 36 above the element isolation portion 3 is set to 60 nm, the height of the third electrode 30 in the Z direction can be set to about 380 nm. A part of the element isolation portion 3 having a thickness of about 30 nm remains below the bottom portion of the third electrode 30.

A case in which the third electrode 30 is disposed with the above-described dimensions is compared with a structure in which the third electrode is assumed to be disposed on the element isolation portion 3.

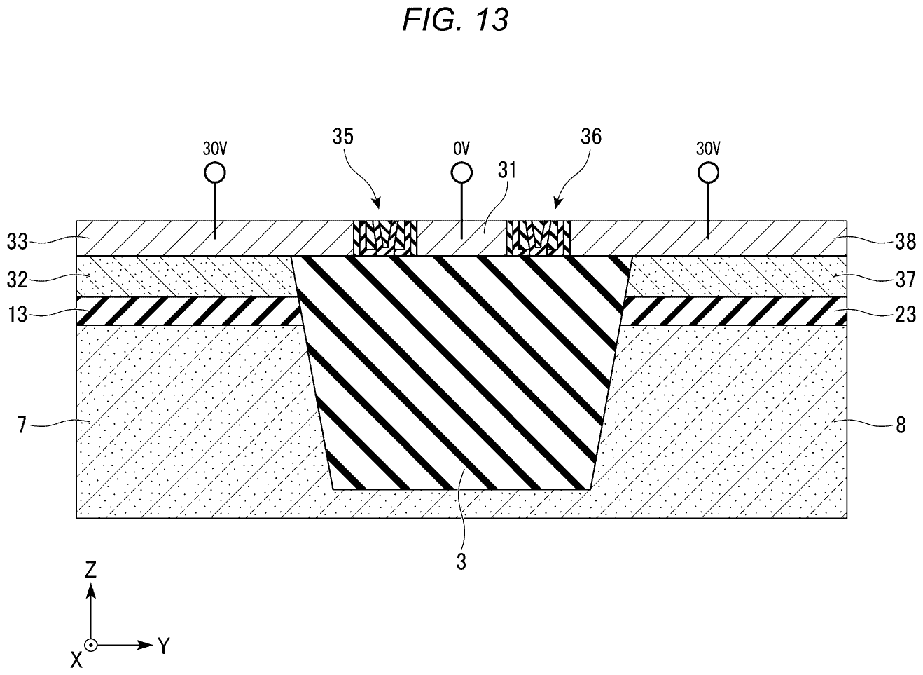

FIG. 13 illustrates the structure of a comparative example in which the lower end of a third electrode 31 is disposed on the upper surface of the element isolation portion 3, a first gate electrode 33 is provided on the first gate insulation film 13 via a first semiconductor layer 32, and a second gate electrode 38 is provided on the second gate insulation film 23 via a second semiconductor layer 37.

For the structure of the comparative example illustrated in FIG. 13, a case in which the width of the third electrode 30 is assumed to be 100 nm, and the depth of the concave groove 3A provided at the element isolation portion 3 is assumed to be 100 nm is considered. The relation equation between electric field and potential difference is E=V/d (where electric field E, potential difference V, distance d). In this case, compared with the configuration in which the lower end of the third electrode 30 is disposed on the upper surface of the element isolation portion 3, the electric field effect exerted by the third electrode 30 as shield gate electrode is 1.4 times (=350/250).

As can be seen from the above description, the structure illustrated in FIG. 2 has a higher leakage current cut-off effect or a higher electric field effect exerted as a shield gate electrode than the structure illustrated in FIG. 13. For example, as described above, good results can be obtained even when the depth of the concave groove 3A is 320 nm or 100 nm with respect to the thickness of the element isolation portion 3 (i.e., 350 nm).

As a result, by forming the concave groove 3A at the element isolation portion 3 and providing the third electrode 30 in the concave groove 3A, it is possible to prevent an inter-element leak current from leaking from the source/drain region of the first transistor 5 to the side of the second transistor 6 through the bottom portion side of the element isolation portion 3. On the contrary, it is possible to prevent an inter-element leak current from leaking from the source/drain region of the second transistor 6 to the side of the first transistor 5 through the bottom portion side of the element isolation portion 3.

In addition, since the inter-element leak current can be prevented by the element isolation portion 3, the element isolation breakdown voltages of the first transistor 5 and the second transistor 6 can be improved as compared with a structure in the related art in which the third electrode 30 is not provided in the concave groove. In addition, since the element isolation breakdown voltages are improved, the element isolation portion 3 can be set to have a narrower width than the structure in the related art, and the interval between the first transistor 5 and the second transistor 6 can be reduced. Accordingly, the high integration of the transistors installed can be achieved.

### Method for Manufacturing Transistor

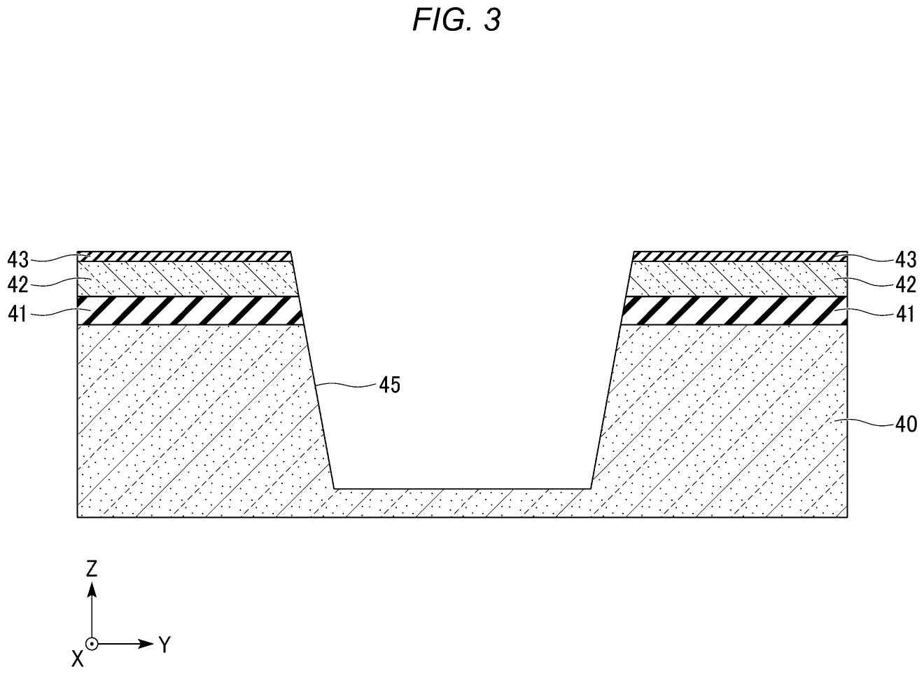

FIG. 3 to FIG. 12 are diagrams illustrating a manufacturing method related to a structure provided with the element isolation portion and the third electrode according to the first embodiment.

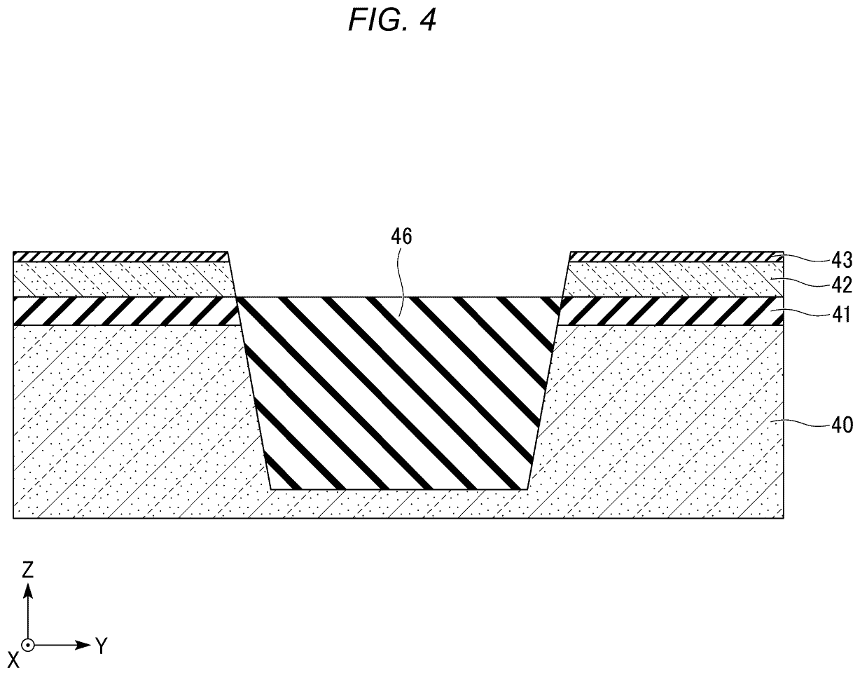

As illustrated in FIG. 3, a gate insulation film 41 is formed at required locations of a semiconductor substrate 40, a first semiconductor layer 42 such as polysilicon and an insulation layer 43 such as SiN are stacked, and a concave groove 45 having a predetermined depth is formed in a region in which an element isolation portion is to be formed. An insulation filler material is deposited on the semiconductor substrate 40, and an element isolation portion 46 is formed so as to fill the inside of the concave groove 45 up to the upper surface of the gate insulation film 41 as illustrated in FIG. 4 by performing CMP, ion etching, etch-back processing, and the like. Subsequently, the insulation layer 43 is removed by a process such as reactive ion etching (RIE) or wet etching (WET).

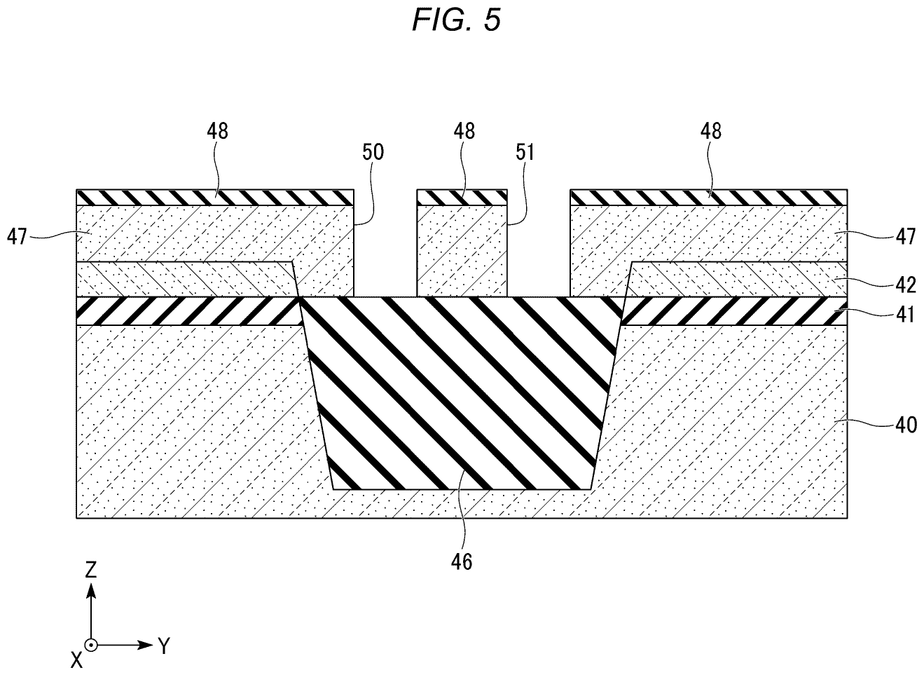

Next, a second semiconductor layer 47 and a cap insulation layer 48 of SiN are formed as illustrated in FIG. 5, and the layers above the element isolation portion 46 are etched to form a first concave groove 50 and a second concave groove 51 along the element isolation portion 46.

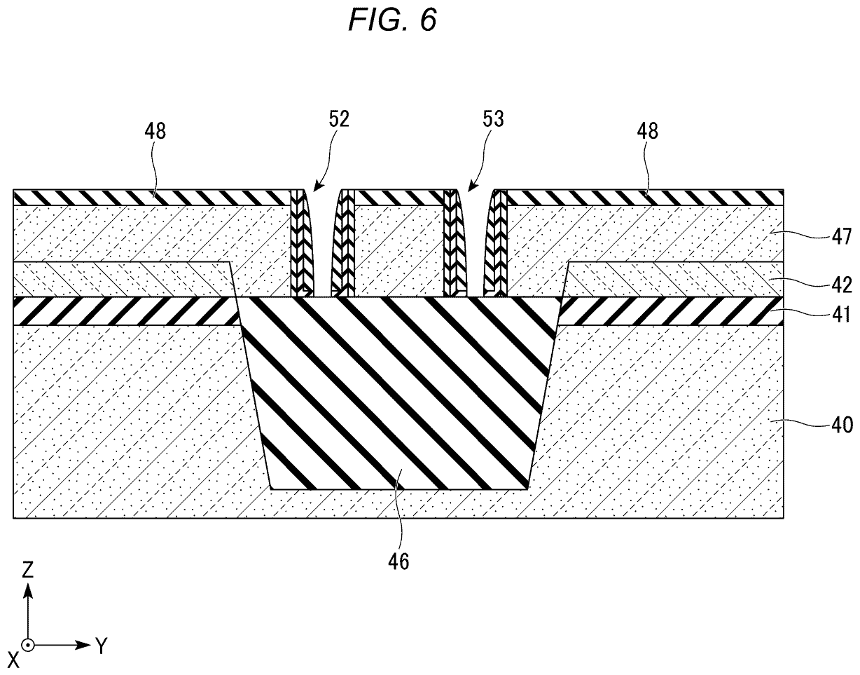

After that, by using films used to form a protective film, an insulation sidewall, or the like of a CMOS transistor (not illustrated), insulation layers 52 and 53 having a stacked structure including a first layer, a second layer, and a third layer are formed inside the first concave groove 50 and the second concave groove 51 as illustrated in FIG. 6.

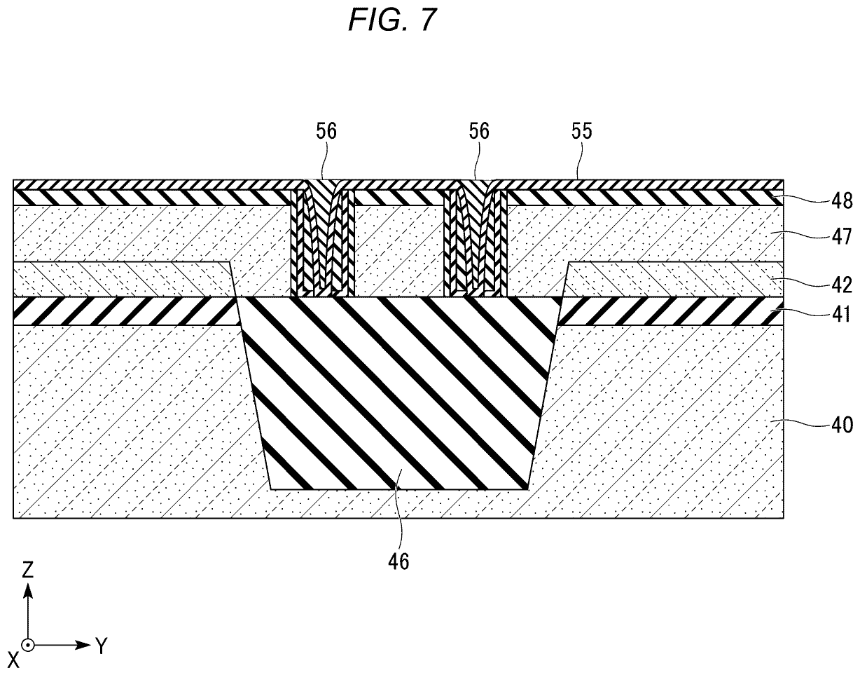

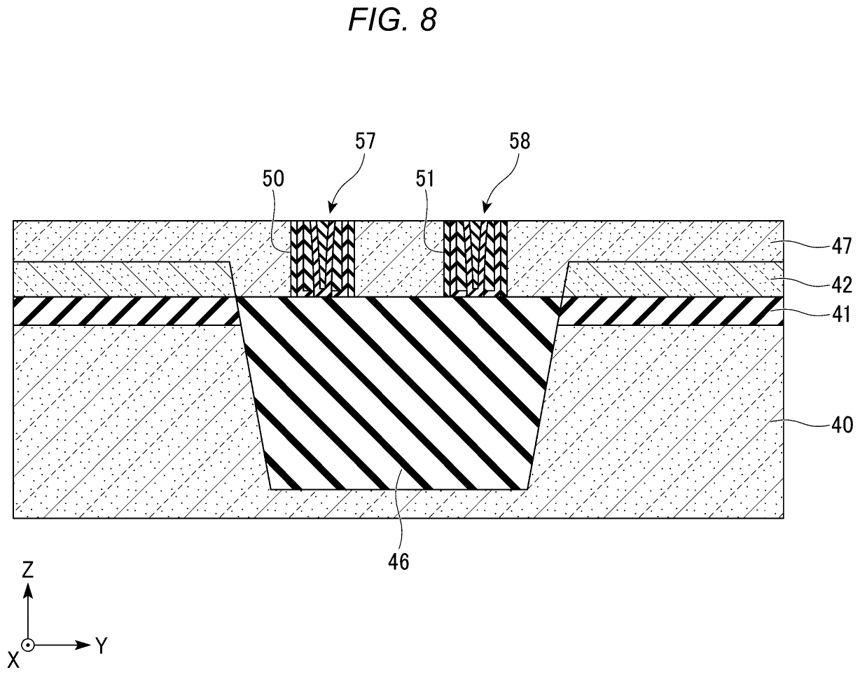

Next, a fourth layer 55 and a fifth layer 56 are formed to fill the first concave groove 50, the second concave groove 51, and the insulation layers 52 and 53 as illustrated in FIG. 7, and then the upper surface is removed to a predetermined thickness by CMP to be flattened, thereby obtaining a structure in which a first insulation portion 57 is embedded in the first concave groove 50 and a second insulation portion 58 is embedded in the second concave groove 51 as illustrated in FIG. 7. Subsequently, the uppermost surface of the structure illustrated in FIG. 7 is etched by, for example, reactive ion etching or wet etching to obtain the structure illustrated in FIG. 8.

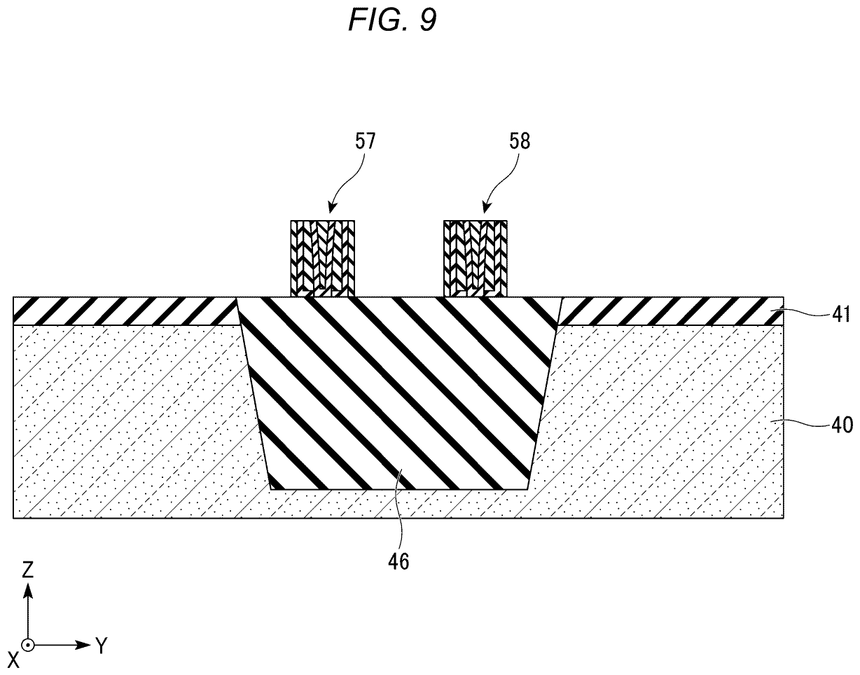

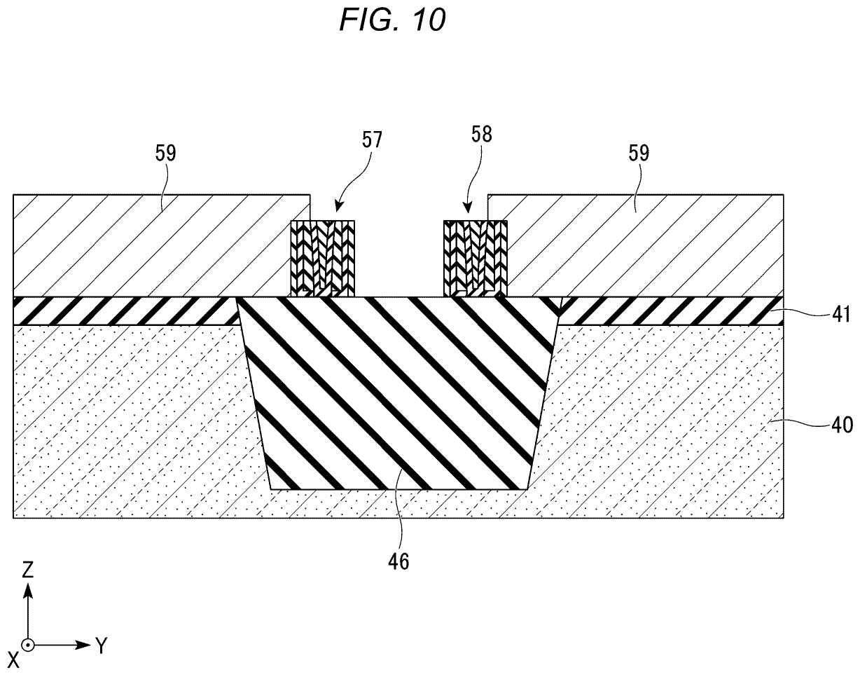

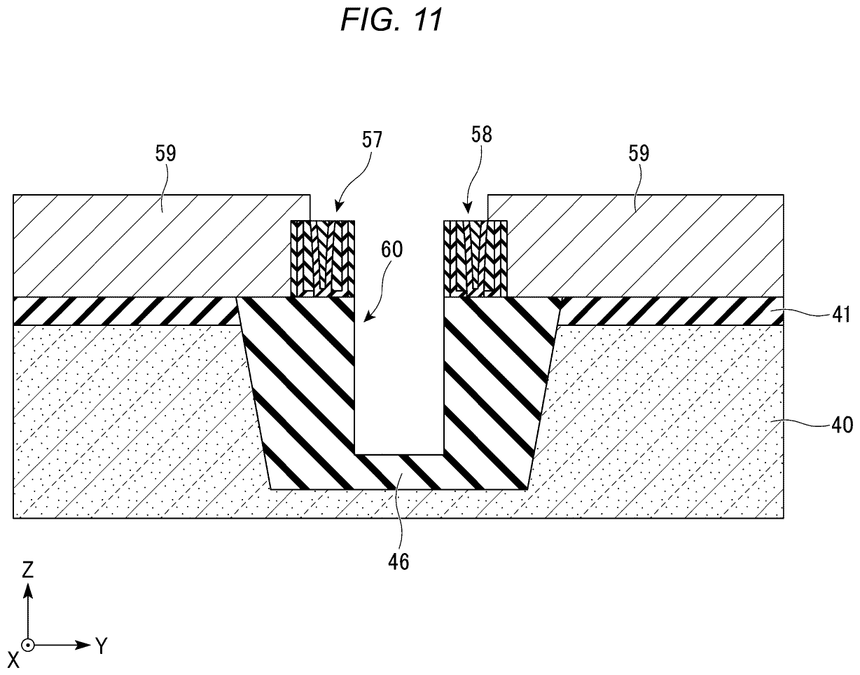

Next, the first semiconductor layer 42 and the second semiconductor layer 47 are removed as illustrated in FIG. 9, a photoresist layer 59 is formed as illustrated in FIG. 10, and a concave groove 60 is formed in the element isolation portion 46 between the first insulation portion 57 and the second insulation portion 58 as illustrated in FIG. 11.

Next, after removing the photoresist layer 59, a stacked film 61B is formed by depositing a plurality of films including a high dielectric constant film 61a in a region in which the gate electrode of the first transistor is to be formed, and an electrode main body portion 61A is formed to form a first gate electrode 61.

Similarly, a stacked film 62B is formed by depositing a plurality of films including a high dielectric constant film 62a in a region in which the gate electrode of the second transistor is to be formed, and an electrode main body portion 62A is formed to form a second gate electrode 62.

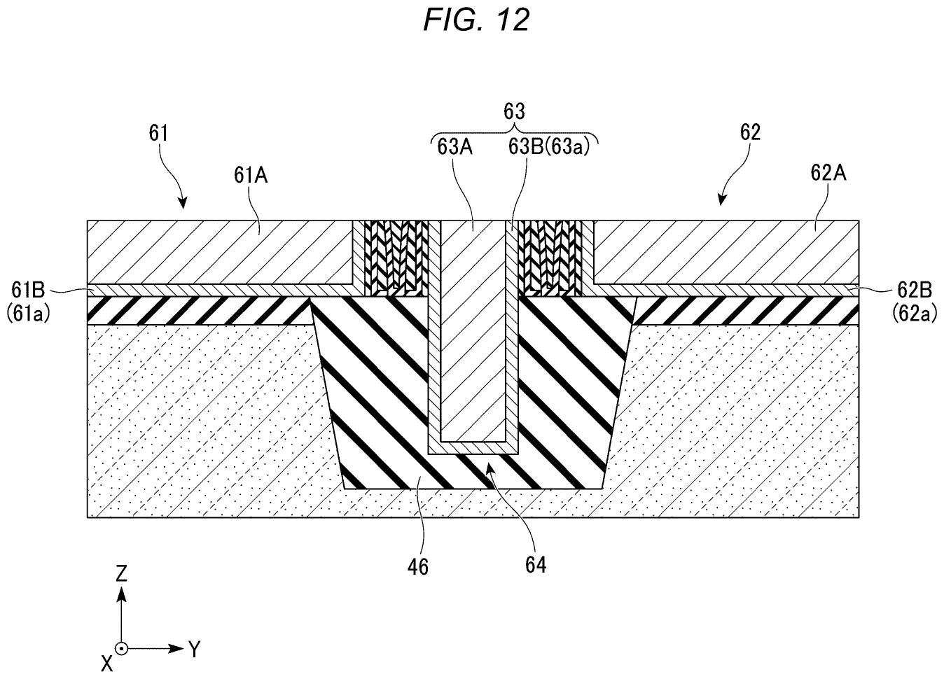

Similarly, a stacked film 63B is formed by depositing a plurality of films including a high dielectric constant film 63a in a region in which the third electrode is to be formed, and an electrode main body portion 63A is formed to form a third electrode 63. Subsequently, a portion in which, due to the formation of the electrode main body portions 61A, 62A, and 63A, deposited film parts of the electrode main body portions are continuous with each other on the upper side thereof is polished and removed by CMP. As a result, the first gate electrode 61, the second gate electrode 62, and the third electrode are separated from each other as illustrated in FIG. 12.

By the above-described manufacturing method, the structure illustrated in FIG. 12, which is equivalent to the structure illustrated in FIG. 2, can be obtained.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a semiconductor substrate including a first surface and a second surface that is opposite to the first surface, the first surface including first and second channel surfaces;
an element isolation portion in the semiconductor substrate and by which the first and second channel surfaces are insulated from each other;
a first transistor including a first gate insulation film on the first channel surface and a first gate electrode on the first gate insulation film;
a second transistor including a second gate insulation film on the second channel surface and a second gate electrode on the second gate insulation film; and
a third electrode on the element isolation portion, wherein
a bottom portion of the third electrode is embedded in the element isolation portion to be closer to the second surface of the substrate than the first and second channel surfaces.

2. The semiconductor device according to claim 1, wherein
each of the first and second gate electrodes includes an insulation film containing a high dielectric constant material and a metal film on the insulating film.

3. The semiconductor device according to claim 2, wherein
the high dielectric constant material has a dielectric constant higher than SiO2 contained in the substrate.

4. The semiconductor device according to claim 3, wherein
the insulation film is a hafnium oxide film.

5. The semiconductor device according to claim 1, wherein
the third electrode includes an insulation film containing a high dielectric constant material and a metal film on the insulation film.

6. The semiconductor device according to claim 5, wherein
the insulation film is a hafnium oxide film.

7. The semiconductor device according to claim 5, wherein
the third electrode includes an electrode body having side and bottom surfaces that are surrounded by the metal film.

8. The semiconductor device according to claim 1, further comprising:
first and second diffusion layer regions between which the first gate electrode is disposed, and
third and fourth diffusion layer regions between which the second gate electrode is disposed, wherein
the third electrode extends between the first and third diffusion layer regions and between the second and fourth diffusion layer regions.

9. The semiconductor device according to claim 1, wherein
the third electrode does not penetrate the element isolation portion.

10. The semiconductor device according to claim 1, wherein
each of the first and second transistors is capable of outputting a voltage of 20 V or higher.

11. A semiconductor device comprising:
a semiconductor substrate including a first surface and a second surface that is opposite to the first surface;
an insulator extending in the first surface;
a first transistor including a first gate insulation film above the first surface and a first gate electrode on the first gate insulation film;
a second transistor including a second gate insulation film above the first surface and a second gate electrode on the second gate insulation film; and
a third electrode disposed on the insulator between the first and second transistors such that a bottom surface of the third electrode is embedded in the insulator and is closer to the second surface of the substrate than the first surface.

12. The semiconductor device according to claim 11, wherein
each of the first and second gate electrodes includes an insulation film containing a high dielectric constant material and a metal film on the insulating film.

13. The semiconductor device according to claim 12, wherein
the high dielectric constant material has a dielectric constant higher than SiO2 contained in the substrate.

14. The semiconductor device according to claim 13, wherein
the insulation film is a hafnium oxide film.

15. The semiconductor device according to claim 11, wherein
the third electrode includes an insulation film containing a high dielectric constant material and a metal film on the insulation film.

16. The semiconductor device according to claim 15, wherein
the insulation film is a hafnium oxide film.

17. The semiconductor device according to claim 15, wherein
the third electrode includes an electrode body having side and bottom surfaces that are surrounded by the metal film.

18. The semiconductor device according to claim 11, further comprising:
first and second diffusion layer regions between which the first gate electrode is disposed, and
third and fourth diffusion layer regions between which the second gate electrode is disposed, wherein
the third electrode extends between the first and third diffusion layer regions and between the second and fourth diffusion layer regions.

19. The semiconductor device according to claim 11, wherein
each of the first and second transistors is capable of outputting a voltage of 20 V or higher.

20. The semiconductor device according to claim 11, wherein
a cross section of the third electrode has a trapezoidal shape.
